(19) United States
(12) Patent Application Publication
(10) Pub. No.: US 2026/0173522 A1
(43) Pub. Date: Jun. 18, 2026

(54) STANDARD CELLS WITH UNBALANCED P/N STRENGTH

(71) Applicant: QUALCOMM Incorporated, San Diego, CA (US)

(72) Inventors: Raheel AZMAT, Cork (IE); Vishal SRIVASTAVA, Cork (IE); Vasisht Mantra VADI, San Diego, CA (US)

(21) Appl. No.: 18/980,828

(22) Filed: Dec. 13, 2024

(51) Int. Cl. H10D 84/90

(52) U.S. Cl. CPC H10D 84/977; H10D 84/981

(57) ABSTRACT

A chip includes a first rail extending in a first direction, a second rail extending in the first direction, and a first cell. The first cell includes a first p-type diffusion region extending in the first direction, a second p-type diffusion region extending in the first direction, a first n-type diffusion region extending in the first direction, and a first gate extending over the first p-type diffusion region, the second p-type diffusion region, and the first n-type diffusion region in a second direction perpendicular to the first direction.

### BACKGROUND

### Field

Aspects of the present disclosure relate generally to chip layout, and more particularly, to unbalanced cells.

### Background

A chip includes many transistors for performing various functions on the chip. The transistors may be implemented using gate-all-around field effect transistors (GAAFETs), fin field effect transistors (FinFETs), and/or other types of transistors. Transistors on the chip may be organized into cells. Each cell may include one or more transistors that are arranged to implement a circuit (e.g., an inverter, a driver, a logic gate, combinational logic, or another type of circuit).

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later

A first aspect relates to a chip. The chip includes a first rail extending in a first direction, a second rail extending in the first direction, and a first cell. The first cell includes a first p-type diffusion region extending in the first direction, a second p-type diffusion region extending in the first direction, a first n-type diffusion region extending in the first direction, and a first gate extending over the first p-type diffusion region, the second p-type diffusion region, and the first n-type diffusion region in a second direction perpendicular to the first direction.

A second aspect relates to a chip. The chip includes a first rail extending in a first direction and a second rail extending in the first direction, wherein the first rail and the second rail are spaced apart by a first height in a second direction perpendicular to the first direction. The chip also includes a first cell, wherein the first cell has a second height in the second direction approximately equal to the first height. The first cell includes a first n-type diffusion region extending in the first direction, a first p-type diffusion region extending in the first direction, wherein the first p-type diffusion region has a longer length in the first direction than the first n-type diffusion region, a first gate extending over the first p-type diffusion region and the first n-type diffusion region in the second direction, and a second gate extending over the first p-type diffusion region in the second direction, wherein the second gate is spaced apart from the first gate in the first direction.

### BRIEF DESCRIPTION OF THE DRAWINGS

FIG. 1A shows a side view of an example of a chip including a transistor and multiple layers according to certain aspects of the present disclosure.

FIG. 1B shows a perspective view of the transistor implemented with a gate-all-around FET according to certain aspects of the present disclosure.

FIG. 2A shows an example of a cell according to certain aspects of the present disclosure.

FIG. 2B shows an example of the cell of FIG. 2A in which the orientation of the cell is flipped in a y direction according to certain aspects of the present disclosure.

FIG. 2C shows an example of the cell including a p-type diffusion region and an n-type diffusion region where the p-type diffusion region is wider than the n-type diffusion region according to certain aspects of the present disclosure.

FIG. 2D shows an example of the cell including a p-type diffusion region and an n-type diffusion region where the n-type diffusion region is wider than the p-type diffusion region according to certain aspects of the present disclosure.

FIG. 3A shows an example of an unbalanced cell including a first p-type diffusion region, a second p-type diffusion region, and an n-type diffusion region according to certain aspects of the present disclosure.

FIG. 3B shows an example in which each of the first p-type diffusion region and the second p-type diffusion region is wider than the n-type diffusion region according to certain aspects of the present disclosure.

FIG. 3C shows an example of the unbalanced cell of FIG. 3A in which the orientation of the unbalanced cell is flipped in a y direction according to certain aspects of the present disclosure.

FIG. 4A shows an example of an unbalanced cell including a first n-type diffusion region, a second n-type diffusion region, and a p-type diffusion region according to certain aspects of the present disclosure.

FIG. 4B shows an example in which each of the first n-type diffusion region and the second n-type diffusion region is wider than the p-type diffusion region according to certain aspects of the present disclosure.

FIG. 4C shows an example of the unbalanced cell of FIG. 4A in which the orientation of the unbalanced cell is flipped in a y direction according to certain aspects of the present disclosure.

FIG. 5 shows an exemplary layout of rows on a chip according to certain aspects of the present disclosure.

FIG. 6 shows an exemplary layout of rails extending over the rows of FIG. 5 according to certain aspects of the present disclosure.

FIG. 7 shows an example of unbalanced cells placed in the rows of FIG. 5 according to certain aspects of the present disclosure.

FIG. 8 shows an example of diffusion regions and gates in the unbalanced cells of FIG. 7 according to certain aspects of the present disclosure.

FIG. 9A shows an example in which two of the cells in FIG. 8 include contacts to implement drivers according to certain aspects of the present disclosure.

FIG. 9B shows an example in which another two of the cells in FIG. 8 include contacts to implement drivers according to certain aspects of the present disclosure.

FIG. 10 shows another example of unbalanced cells placed in the rows of FIG. 5 according to certain aspects of the present disclosure.

FIG. 11 shows an example of diffusion regions and gates in the unbalanced cells of FIG. 10 according to certain aspects of the present disclosure.

FIG. 12 shows an example in which the cells of FIG. 11 include contacts to implement drivers according to certain aspects of the present disclosure.

FIG. 13 shows an example of an unbalanced cell including a p-type diffusion region with multiple fingers according to certain aspects of the present disclosure.

FIG. 14 shows an example of an unbalanced cell including an n-type diffusion region with multiple fingers according to certain aspects of the present disclosure.

FIG. 15 shows another example of unbalanced cells placed in the rows of FIG. 5 according to certain aspects of the present disclosure.

FIG. 16 shows an example of diffusion regions and gates in the unbalanced cells of FIG. 15 according to certain aspects of the present disclosure.

FIG. 17 shows an exemplary layout of rows having different heights according to certain aspects of the present disclosure.

FIG. 18 shows an exemplary layout of rails extending over the rows of FIG. 17 according to certain aspects of the present disclosure.

FIG. 19 shows an example of a digital block in which aspects of the present disclosure may be used.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

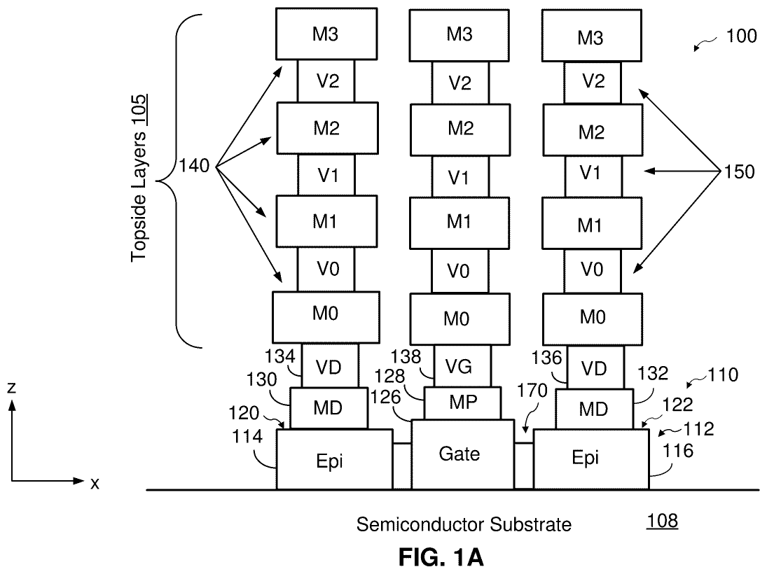

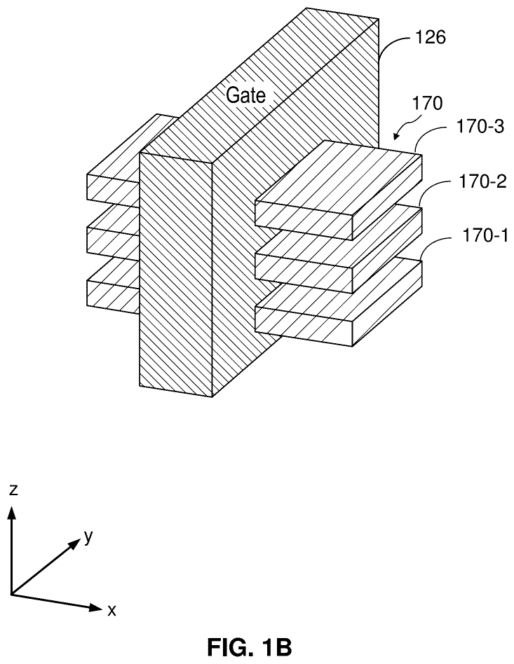

FIG. 1A shows a side view of an example of a chip 100 (e.g., a die) including a transistor 110 and multiple topside layers 105 (also referred to as frontside layers) according to certain aspects. Although one transistor 110 is shown in FIG. 1A for simplicity, it is to be appreciated that the chip 100 includes many transistors. As discussed further below, the transistor 110 may be implemented using a gate-all-around field effect transistor (FET) process, a fin field-effect transistor (FinFET) process, or another type of process. The topside layers 105 are above the transistor 110 in the z direction shown in FIG. 1A. The transistor 110 and the topside layers 105 may be formed on a semiconductor substrate 108 (e.g., silicon substrate).

In the example shown in FIG. 1A, the transistor 110 includes a diffusion region 112 and a gate 126 on the diffusion region 112. The diffusion region 112 may also be referred to as an oxide diffusion region, an active region, active diffusion, active (RX), or another term. The gate 126 may be formed on the diffusion region 112, and may include a gate metal (e.g., a high-k metal gate (HKMG)), polysilicon, and/or another gate material. The diffusion region 112 includes one or more channels 170 extending in the x direction in FIG. 1A, where the x direction is perpendicular to the z direction. As used herein, a “channel” is a structure that conducts current between a source and a drain of a transistor.

For a gate-all-around FET process, the diffusion region 112 may correspond to an area of the chip 100 where one or more nanosheets are formed, in which the gate 126 is formed around a portion of the one or more nanosheets to provide the one or more channels 170. In this example, portions of the one or more nanosheets outside of the gate 126 may be cut and epi layers may be coupled to opposite sides of the one or more channels 170, as discussed further below.

For the example of a gate-all-around FET process, the gate 126 may surround each of the one or more channels 170 (also referred as ribbons) on four sides. In this regard, FIG. 1B shows a perspective view in which the one or more channels 170 include channels 170-1, 170-2, and 170-3 where each of the channels 170-1, 170-2, and 170-3 passes through the gate 126 and is surrounded on four sides by the gate 126. Each of the channels 170-1, 170-2, and 170-3 may include a nanosheet, a nanowire, or the like. In this example, the channels 170-1, 170-2, and 170-3 are stacked vertically and are spaced apart from one another in the z direction. However, it is to be appreciated that the present disclosure is not limited to this example. For the example of a FinFET process, each of the one or more channels may include a fin that passes through the gate and is surrounded by on three sides by the gate 126.

Returning to FIG. 1A, the transistor 110 may include a first epitaxial (epi) layer 114 and a second epi layer 116 in which the gate 126 is disposed between the first epi layer 114 and the second epi layer 116. The first epi layer 114 is coupled to the one or more channels 170 on one side of the gate 126 to provide a first source/drain 120. The second epi layer 116 is coupled to the one or more channels 170 on the other side of the gate 126 to provide a second source/drain 122. An epi layer may also be referred to as simply epi or another term. As used herein, the term “source/drain” means a source, a drain, or both a source and a drain.

As shown in FIG. 1A, the first epi layer 114 and the second epi layer 116 are located on opposite sides of the gate 126. Each of the first epi layer 114 and the second epi layer 116 may include epitaxially grown or deposited silicon, a silicon-based material (e.g., silicon-germanium), or any combination thereof. In this example, the gate 126 controls the conductivity between the first source/drain 120 and the second source/drain 122 based on a voltage applied to the gate 126. The transistor 110 may include a thin spacer (not shown in FIG. 1A) between the gate 126 and the first epi layer 114, and a thin spacer (not shown in FIG. 1A) between the gate 126 and the second epi layer 116. A spacer may also be referred to as a sidewall spacer or another term.

In this example, the chip 100 includes a first contact 130 formed on a top surface of the first source/drain 120 and a second contact 132 formed on a top surface of the second source/drain 122. A top surface may also be referred to as a frontside surface. The contacts 130 and 132 may be formed (i.e., patterned) from a contact layer using, for example, lithographic and etching processes. Each of the contacts 130 and 132 may be referred to as a metal-diffusion (MD) contact, contact active (CA), or another term. Each of the contacts 130 and 132 may include cobalt (Co), tungsten (W), molybdenum (Mo), another conductive material, or any combination thereof.

The chip 100 may also include a gate contact 128 formed on the gate 126. The gate contact 128 may be referred to as a metal-poly (MP) contact or another term. The gate contact 128 may be omitted in some implementations.

In this example, the topside layers 105 include metal layers 140 (also referred to as a metal stack). The metal layers 140 may be patterned (e.g., using lithography and etching) to provide signal routing for the transistor 110 and other transistors (not shown in FIG. 1A) integrated on the chip 100. The metal layers 140 may also be patterned to form a power distribution network including positive supply rails for distributing power to the transistor 110 and other transistors integrated on the chip 100. A positive supply rail may also be referred to as a power rail, a supply rail, Vdd rail, or another term.

In the example in FIG. 1A, the bottom-most metal layer among the metal layers 140 is referred to as metal layer M0. The metal layer immediately above metal layer M0 is referred to as metal layer M1, the metal layer immediately above metal layer M1 is referred to as metal layer M2, the metal layer immediately above metal layer M2 is referred to as metal layer M3, and so forth. Although four metal layers 140 (i.e., M0 to M3) are shown in FIG. 1A for ease of illustration, it is to be appreciated that the topside layers 105 may include additional metal layers above metal layer M3. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0. Also, it is to be appreciated that one or more of the metal layers may be designated with a letter other than M in other examples. Accordingly, it is to be appreciated that the metal layers are not limited to the exemplary designations used in FIG. 1A.

The topside layers 105 also includes vias 150 that provide coupling between the metal layers 140. The vias 150 include vias V0, vias V1, and vias V2. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1A, the chip 100 also includes a via 138 disposed between the gate contact 128 and metal layer M0, in which the via 138 couples the gate contact 128 (and hence the gate 126) to metal layer M0. For implementations where the gate contact 128 is omitted, the via 138 may be disposed between the gate 126 and metal layer M0 without an intervening gate contact. In this example, the chip 100 also includes a via 134 disposed between the contact 130 and metal layer M0, in which the via 134 couples the contact 130 to metal layer M0. The chip 100 also includes a via 136 disposed between the contact 132 and metal layer M0, in which the via 136 couples the contact 132 to metal layer M0.

Although one gate 126 is shown in FIGS. 1A and 1B, it is to be appreciated that the transistor 110 may include multiple gates arranged in parallel and coupled to one another (e.g., through metal layer M0 or another metal layer). A transistor with multiple gates may be referred to as a multi-gate transistor, a multi-finger transistor, or another term.

Transistors on the chip 100 may be organized into cells. Each cell may include one or more transistors that are arranged to implement a circuit (e.g., an inverter, a driver, a logic gate, combinational logic, a latch, a flip-flop, a bit cell, or another type of circuit). The layout of each cell may be specified (i.e., defined) in a standard cell library, which may be stored in a memory. The standard cell library may specify (i.e., define) the layout of each one of various cells that can be placed (i.e., laid out) on the chip 100 for a particular process. The chip 100 may include multiple instances of a particular cell defined in the standard cell library. The layout of each cell defined in the standard cell library may include the layout of gates, diffusion regions, and contacts in the cell. A cell that is defined in a standard cell library may also be referred to as a standard cell.

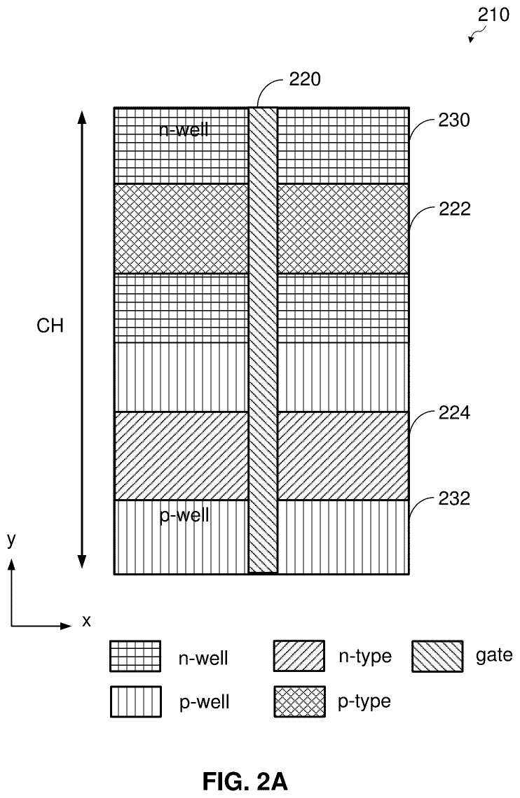

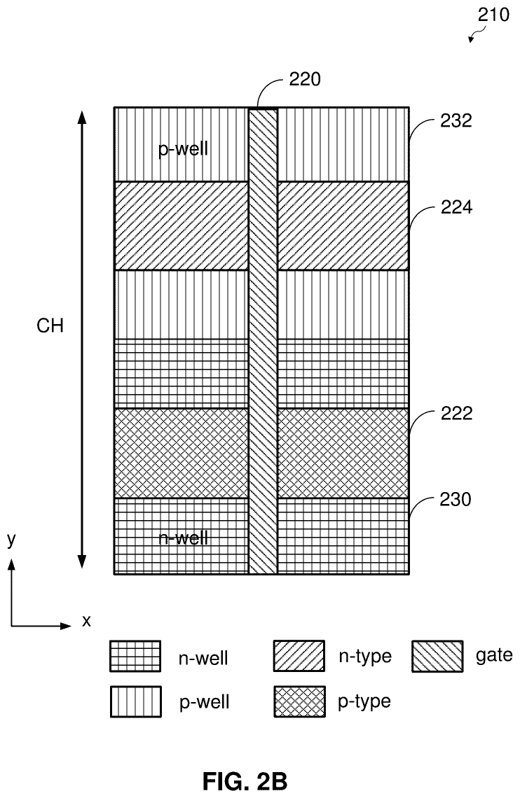

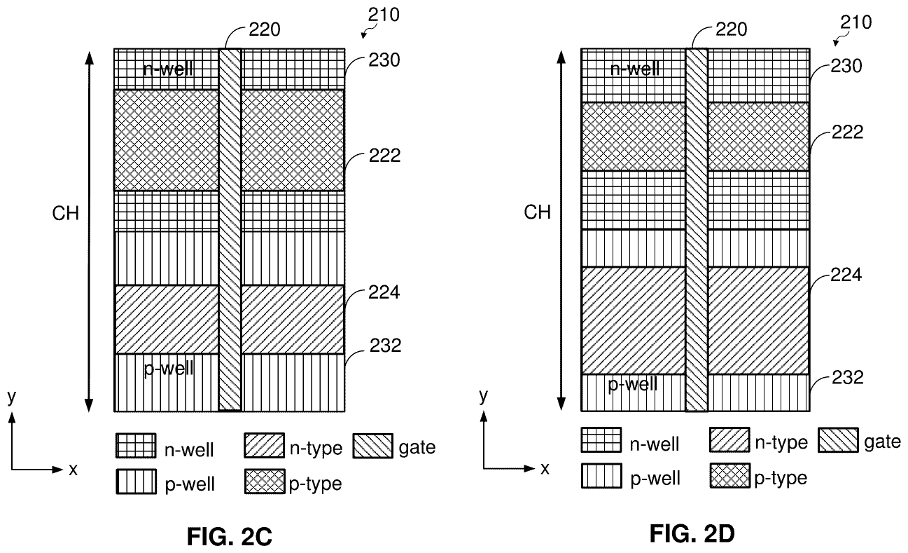

FIG. 2A shows a top view of an example of a cell 210. The cell 210 includes a p-type diffusion region 222 and a n-type diffusion region 224 extending in the x direction. Each of the diffusion regions 222 and 224 may be a respective instance of the diffusion region 112 where each of the diffusion regions 222 and 224 includes a respective instance of the one or more channels 170 (e.g., nanosheets). In this example, the chip includes an n-well 230 and a p-well 232 in which the p-type diffusion region 222 is formed over the n-well 230 and the n-type diffusion region 224 is formed over the p-well 232.

The cell 210 also includes a gate 220 (e.g., the gate 126) extending in the y direction over the diffusion regions 222 and 224. The p-type diffusion region 222 and the gate 220 form a p-type field effect transistor (PFET) and the gate 220 and the n-type diffusion region 224 form an n-type field effect transistor (NFET). In the example shown in FIG. 2A, the PFET and the NFET share the gate 220. However, it is to be understood that the gate 220 may be cut between the p-type diffusion region 222 and the n-type diffusion region 224 to provide separate gates for the PFET and the NFET in other implementations. Also, although the gate 220 is shown extending the full height of the cell 210 in the y direction in FIG. 2A, it is to be appreciated that the height of the gate 220 may be slightly less than the height of the cell 210 (labeled “CH” in FIG. 2A).

In the example shown in FIG. 2A, the cell 210 is balanced in which the widths of the diffusion regions 222 and 224 are equal in the y direction. For the example where the cell 210 is fabricated using a gate-all-around FET process, the channels (e.g., nanosheets) of the diffusion regions 222 and 224 have equal widths in the y direction.

In many cases, unbalanced cells are used to improve critical timing paths in digital blocks. An unbalanced cell may be a cell in which the width of the p-type diffusion region 222 and the width of the n-type diffusion region 124 in the y direction are different (e.g., to skew the strengths of the PFET and the NFET in the cell).

It is to be appreciated that the orientation of the cell 210 may be flipped in the y direction to provide greater flexibility in laying out the cell 210 on the chip. In this regard, FIG. 2B shows an example in which the orientation of the cell 210 is flipped in the y direction. In this example, the locations of the n-type diffusion region 224 and the p-type diffusion region 222 are flipped in the y direction.

FIG. 2C shows an example in which the cell 210 is unbalanced. In this example, the p-type diffusion region 222 is wider than the n-type diffusion region 224 in the y direction. This may be done, for example, to increase the strength of the PFET in order to reduce the rise time of the cell 210. For example, the p-type diffusion region 222 may have a width of 25 nm while the n-type diffusion region 224 has a width of 15 nm.

FIG. 2D shows another example in which the cell 210 is unbalanced. In this example, the n-type diffusion region 224 is wider than the p-type diffusion region 222 in the y direction. This may be done, for example, to increase the strength of the NFET in order to reduce the fall time of the cell 210.

In the examples shown in FIGS. 2A to 2D, the cell 210 has a height of 1 CH (i.e., one cell heigh).

A challenge with implementing unbalanced cells is that existing technologies limit the width difference between the p-type diffusion region 222 and the n-type diffusion region 224. For example, for a gate-all-around process, the width difference may be limited to 10 nm, which may not provide enough skew to meet timing requirement for a critical data path. Accordingly, unbalanced cells with larger skews between PFET strength and NFET strength are desirable.

To address the above, aspects of the present disclosure provide unbalanced cells that enable larger skews between PFET strength and NFET strength. In certain aspects, larger skews are achieved by including multiple p-type diffusion regions in a cell to increase PFET strength relative to NFET strength and including multiple n-type diffusion regions in a cell to increase NFET strength relative to PFET strength. In certain aspects, larger skews are achieved by including a larger number of fingers for the p-type diffusion region than the n-type diffusion region in a cell to increase PFET strength relative to NFET strength and including a larger number of fingers for the n-type diffusion regions than the p-type diffusion region in a cell to increase NFET strength relative to PFET strength. Unbalanced cells according to aspects of the present disclosure may be added to a standard cell library. The above features and other features of the present disclosure are discussed further below.

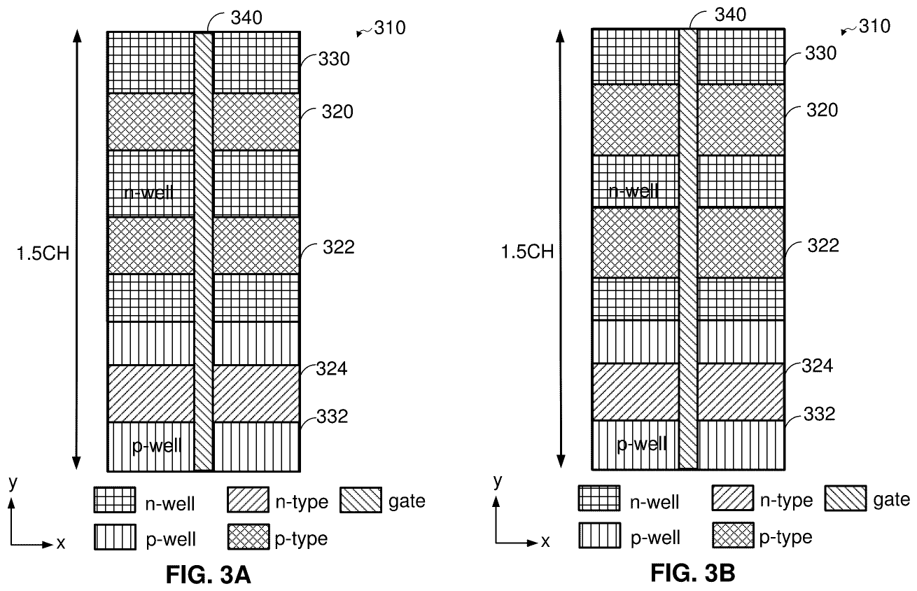

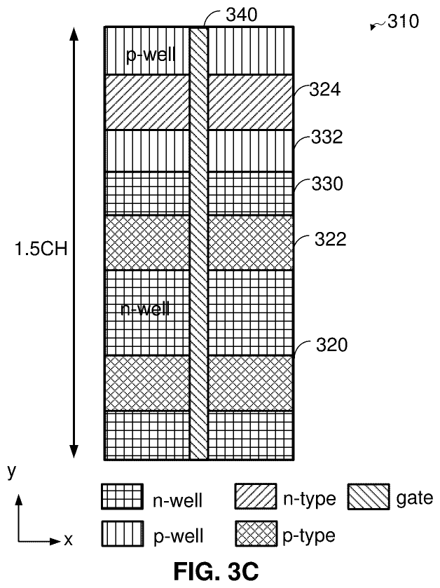

FIG. 3A shows a top view of an example of an unbalanced cell 310 including two p-type diffusion regions to double the strength of the PFET. The two p-type diffusion regions include a first p-type diffusion region 320 and a second p-type diffusion region 322 extending in the x direction over an n-well 330. The first p-type diffusion region 320 and the second p-type diffusion region 322 are spaced apart in the y direction, which is orthogonal to the x direction. Each of the p-type diffusion regions 320 and 322 may be a respective instance of the diffusion region 112 where each of the diffusion regions 320 and 322 includes a respective instance of the one or more channels 170 (e.g., nanosheets).

The unbalanced cell 310 also includes an n-type diffusion region 324 extending in the x direction over a p-well 332. The n-type diffusion region 324 be a respective instance of the diffusion region 112 including a respective instance of the one or more channels 170 (e.g., nanosheets).

The cell 310 also includes a gate 340 (e.g., the gate 126) extending in the y direction over the p-type diffusion regions 320 and 322 and the n-type diffusion regions 324. The p-type diffusion regions 320 and 322 and the gate 340 form the PFET and the n-type diffusion region 324 and the gate 340 form the NFET. In this example, the two p-type diffusion regions 320 and 322 double the strength of the PFET to provide a larger skew between the PFET strength and the NFET strength.

In the example shown in FIG. 3A, the n-type diffusion region 324 has the same width as each of the p-type diffusion regions 320 and 322 taken individual. However, the combined width of the p-type diffusion regions 320 and 322 is approximately double the width of the n-type diffusion region 324 in this example. This provides larger skew between the PFET strength and the NFET strength compared with the example shown in FIG. 2C in which the width difference between the p-type diffusion region 222 and the n-type diffusion region 224 is limited. To provide an even larger skew, each of the p-type diffusion regions 320 and 322 may be made wider than the n-type diffusion region 324 in the y direction, an example of which is shown in FIG. 3B. For example, in some implementations, the width of the n-type diffusion 324 may be approximately equal to 15 nm and the width of each of the p-type diffusion regions 320 and 322 may be approximately equal to 25 nm. However, it is to be appreciated that the present disclosure is not limited to these exemplary dimensions.

It is to be appreciated that the p-type diffusion regions 320 and 322 are not limited to having the same width. For example, in some implementations, the p-type diffusion regions 320 and 322 may have different widths (e.g., depending on different diffusion widths that are available in a process technology).

In the examples shown in FIGS. 3A and 3B, the cell 310 has a height of 1.5 CH compared with the height of 1 CH for the cell 210. This is due to the additional p-type diffusion region in the cell 310.

In the examples shown in FIGS. 3A and 3B, the PFET and the NFET share the gate 340. However, it is to be understood that the gate 340 may be cut between the second p-type diffusion region 322 and the n-type diffusion region 324 in other implementations to provide separate gates for the PFET and the NFET.

It is to be appreciated that the orientation of the cell 310 may be flipped in the y direction to provide greater flexibility in laying out the cell 310 on the chip, as discussed further below. In this regard, FIG. 3C shows an example in which the orientation of the cell 310 is flipped in the y direction. In this example, the locations of the n-type diffusion region 324 and the p-type diffusion regions 320 and 322 are flipped in the y direction.

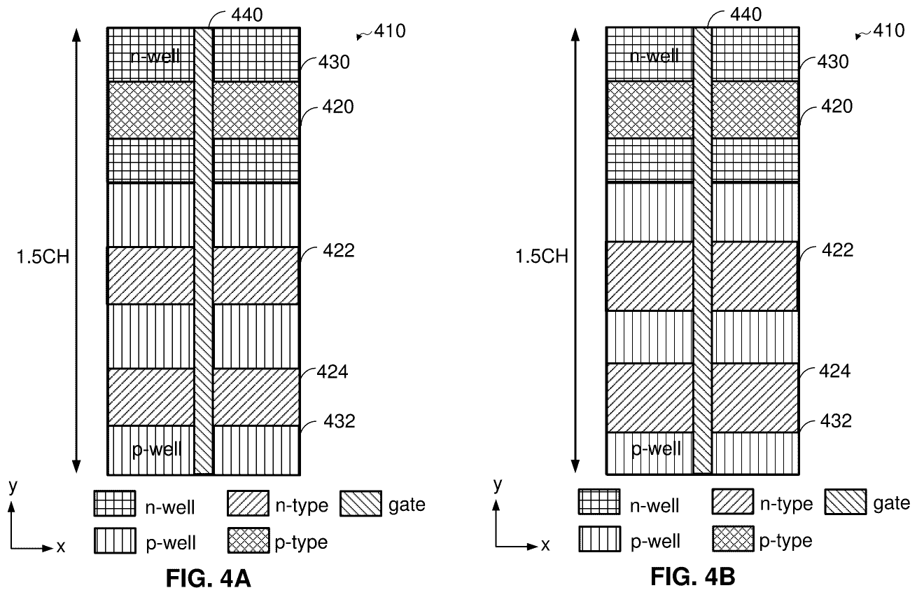

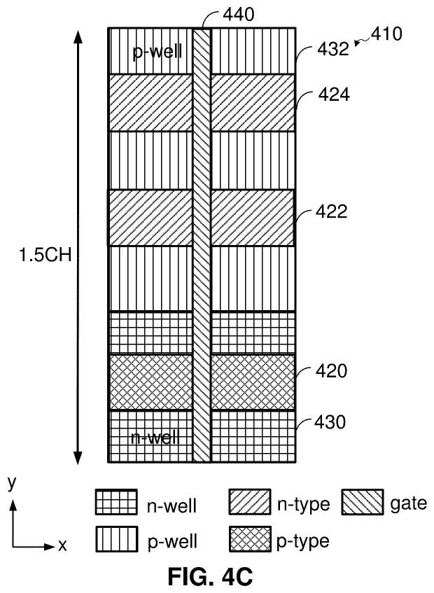

FIG. 4A shows a top view of another example of an unbalanced cell 410 including two n-type diffusion regions to double the strength of the NFET. The two n-type diffusion regions include a first n-type diffusion region 422 and a second n-type diffusion region 424 extending in the x direction over a p-well 432. The first n-type diffusion region 422 and the second n-type diffusion region 424 are spaced apart in the y direction. Each of the n-type diffusion regions 422 and 424 may be a respective instance of the diffusion region 112 where each of the diffusion regions 422 and 424 includes a respective instance of the one or more channels 170 (e.g., nanosheets).

The unbalanced cell 410 also includes a p-type diffusion region 420 extending in the x direction over an n-well 430. The p-type diffusion region 420 be a respective instance of the diffusion region 112 including a respective instance of the one or more channels 170 (e.g., nanosheets).

The cell 410 also includes a gate 440 (e.g., the gate 126) extending in the y direction over the n-type diffusion regions 422 and 424 and the p-type diffusion region 420. The n-type diffusion regions 422 and 424 and the gate 440 form the NFET and the p-type diffusion region 420 and the gate 440 form the PFET. In this example, the two n-type diffusion regions 422 and 424 double the strength of the NFET to provide a larger skew between the NFET strength and the PFET strength.

In the example shown in FIG. 4A, the p-type diffusion region 420 has the same width as each of the n-type diffusion regions 422 and 424 taken individual. However, the combined width of the n-type diffusion regions 422 and 424 is approximately double the width of the p-type diffusion region 420 in this example. This provides larger skew between the NFET strength and the PFET strength compared with the example shown in FIG. 2D in which the width difference between the p-type diffusion region 222 and the n-type diffusion region 224 is limited. To provide an even larger skew, each of the n-type diffusion regions 422 and 424 may be made wider than the p-type diffusion region 420 in the y direction, an example of which is shown in FIG. 4B.

In the examples shown in FIGS. 4A and 4B, the cell 410 has a height of 1.5 CH compared with the height of 1 CH for the cell 210. This is due to the additional n-type diffusion region in the cell 410.

In the examples shown in FIGS. 4A and 4B, the PFET and the NFET share the gate 440. However, it is to be understood that the gate 440 may be cut between the p-type diffusion region 420 and first n-type diffusion region 422 in other implementations to provide separate gates for the PFET and the NFET.

It is to be appreciated that the orientation of the cell 410 may be flipped in the y direction to provide greater flexibility in laying out the cell 410 on the chip, as discussed further below. In this regard, FIG. 4C shows an example in which the orientation of the cell 410 is flipped in the y direction. In this example, the locations of the p-type diffusion region 420 and the n-type diffusion regions 422 and 424 are flipped in the y direction.

The exemplary unbalanced cells 310 and 410 may be used to improve critical timing paths in digital blocks. For example, one or more instances of the unbalanced cell 310 may be used in cases where a faster rise time is needed to meet timing requirements for a data path, and one or more instances of the unbalanced cell 410 may be used in cases where a faster fall time is needed to meet timing requirements for a data path.

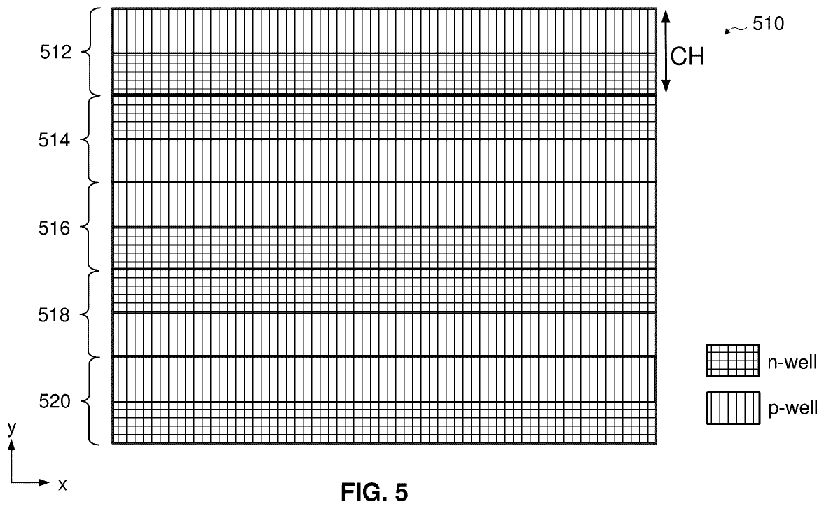

Cells may be arranged (i.e., laid out) in rows on the chip. In this regard, FIG. 5 shows a top view of an exemplary layout 510 for arranging cells in rows 512, 514, 516, 518, and 520 extending in the x direction. Each of the row 512, 514, 516, 518, and 520 includes a p-well and an n-well and has a height of 1 CH. In the example in FIG. 5, the p-well in each of the rows 512, 514, 516, 518, and 520 is contiguous with the p-well in an adjacent row. For example, the p-well in the row 516 is contiguous with the p-well in the adjacent row 514. Also, the n-well in each of the rows 512, 514, 516, 518, and 520 is contiguous with the n-well in an adjacent row. For example, the n-well in the row 516 is contiguous with the n-well in the adjacent row 518.

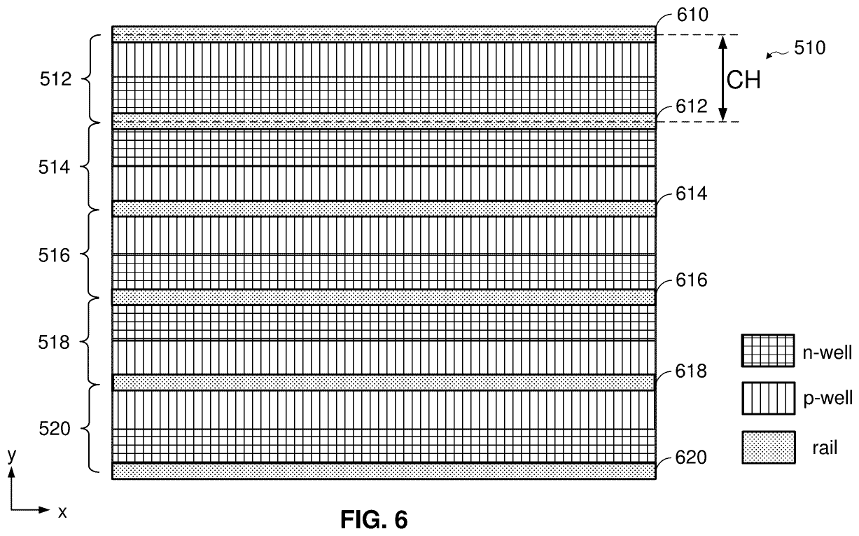

FIG. 6 shows a top view of rails 610, 612, 614, 616, 618, and 620 for distributing power to cells arranged in the rows 512, 514, 516, 518, and 520. Each of the rails 610, 612, 614, 616, 618, and 620 extends in the x direction and may be formed in metal layer M0 shown in FIG. 1A. Each of the rails 610, 612, 614, 616, 618, and 620 lies on the boundaries of two adjacent rows and may be shared by cells in the two adjacent rows. For example, the rail 612 lies on the boundaries of the rows 512 and 514 and may be shared by cells in the rows 512 and 514.

In the example in FIG. 6, adjacent rails are spaced apart by a height (i.e., a pitch) approximately equal to one CH, which is the height of a row and a single-row height cell (e.g., cell 210). As used herein, the space between two adjacent rails is the space between the centerlines of the adjacent rails. An example of this is shown in FIG. 6, in which the centerlines of adjacent rails 610 and 612 are indicated by dashed lines and are spaced apart by one CH.

In certain aspects, each of the rails 610, 614, and 618 is a VSS rail (e.g., a ground rail) and each of the rails 612, 616, and 620 is a VDD rail (also referred to as a supply rail, power rail, or another term). Each of the rails 610, 614, and 618 (i.e., VSS rail in this example) extends over a respective one of the p-wells, and each of the rails 612, 616, and 620 (i.e., VDD rail in this example) extends over a respective one of the n-wells. As a result, the rails 610, 612, 614, 616, 618, and 620 alternate between VDD and VSS in the y direction. This alternating arrangement of VDD and VSS ensures that each of the rows 512, 514, 516, 518, and 520 is between a VDD rail and a VSS rail to provide the cells in each of the rows 512, 514, 516, 518, and 520 with access to VDD and VSS. However, it is to be appreciated that the present disclosure is not limited to this example.

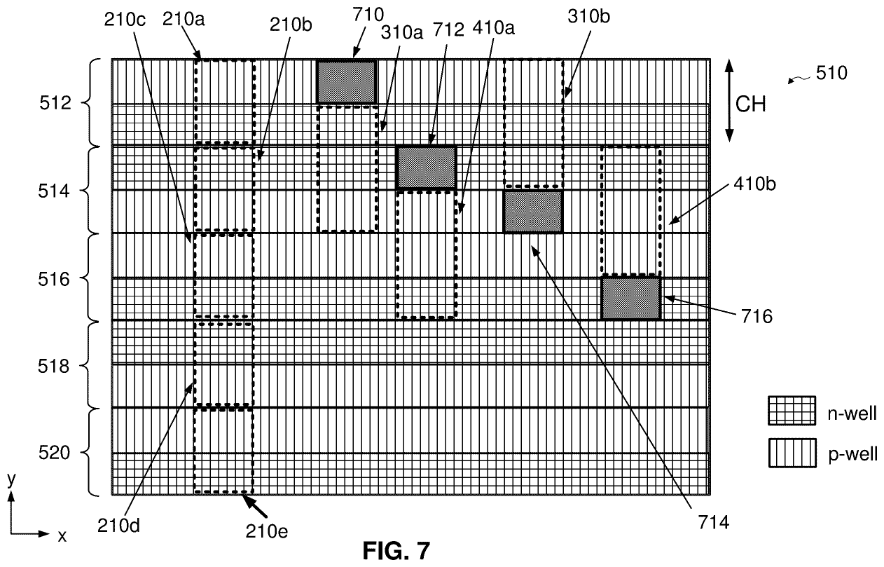

FIG. 7 shows an exemplary layout of various cells that may be placed in the rows 512, 514, 516, 518, and 520. The boundary of each of the cells is delineated by a dotted line in FIG. 7. For ease of illustration, the diffusion regions and the gate(s) of each cell is not shown in FIG. 7.

FIG. 7 shows an example of cells 210a to 210e in which each of the cells 210a and 210e is a separate instance of the cell 210 and has a height of 1 CH. Thus, the description of the cell 210 given above with reference to FIGS. 2A to 2D applies to each of the cells 210a to 210e. Each of the cells 210a to 210e may be balanced (shown in FIG. 2A) or unbalanced (shown in FIGS. 2C and 2D).

In the example in FIG. 7, the cell 210a is placed in the row 512, the cell 210b is placed in the row 514, the cell 210c is placed in the row 516, the cell 210d is placed in the row 518, and the cell 210e is placed in the row 520. Each of the cells 210a, 210c, and 210e may have the orientation shown in FIG. 2B, and each of the cells 210b and 210d may be the orientation shown in FIG. 2A. Although the cells 210a to 210e are shown being aligned in the x direction in FIG. 7, it is to be appreciated that the cells 210a to 210e may be offset from one another in the x direction.

FIG. 7 shows an example of unbalanced cells 310a and 310b in which each of the cells 310a and 310b is a separate instance of the cell 310 and has a height of 1.5 CH. Thus, the description of the cell 310 given above with reference to FIGS. 3A to 3C applies to each of the cells 310a and 310b.

In the example in FIG. 7, the unbalanced cell 310a is placed in the row 514 and partially in the row 512. The cell 310a has the orientation shown in FIG. 3A in which the cell 310a extends across the p-well and the n-well in the row 514 and across the n-well in row 512. In this example, the n-wells in the rows 514 and 512 provide the wide n-well 330 shown in FIG. 3A. A filler cell 710 having a height of 0.5 CH is placed next to the cell 310a (i.e., abuts the cell 310a) to fill the remaining portion of the row 512. Thus, in this example, the unbalanced cell 310a and the filler cell 710 span two rows (i.e., the rows 512 and 514). As used herein, a “filler cell” is a cell that performs no logic function and is used to fill an empty space between cells (e.g., to meet certain design rule checks for the process used to fabricate the chip).

In the example in FIG. 7, the unbalanced cell 310b is placed in the row 512 and partially in the row 514. The cell 310a has the orientation shown in FIG. 3C in which the cell 310b extends across the p-well and the n-well in the row 512 and across the n-well in row 514. In this example, the n-wells in the rows 514 and 512 provide the wide n-well 330 shown in FIG. 3C. A filler cell 714 having a height of 0.5 CH is placed next to the cell 310b to fill the remaining portion of the row 514. Thus, in this example, the unbalanced cell 310b and the filler cell 714 span two rows (i.e., the rows 512 and 514).

FIG. 7 also shows an example of unbalanced cells 410a and 410b in which each of the cells 410a and 410b is a separate instance of the cell 410 and has a height of 1.5 CH. Thus, the description of the cell 410 given above with reference to FIGS. 4A to 4C applies to each of the cells 410a and 410b.

In the example in FIG. 7, the unbalanced cell 410a is placed in the row 516 and partially in the row 514. The cell 410a has the orientation shown in FIG. 4C in which the cell 410a extends across the n-well and the p-well in the row 516 and across the p-well in row 514. In this example, the p-wells in the rows 516 and 514 provide the wide p-well 432 shown in FIG. 4C. A filler cell 712 having a height of 0.5 CH is placed next to the cell 410a to fill the remaining portion of the row 514. Thus, in this example, the unbalanced cell 410a and the filler cell 712 span two rows (i.e., the rows 516 and 514).

In the example in FIG. 7, the unbalanced cell 410b is placed in the row 514 and partially in the row 516. The cell 410b has the orientation shown in FIG. 4A in which the cell 410a extends across the p-well and the n-well in the row 514 and across the p-well in row 516. In this example, the p-wells in the rows 514 and 516 provide the wide p-well 432 shown in FIG. 4A. A filler cell 716 having a height of 0.5 CH is placed next to the cell 410b to fill the remaining portion of the row 516. Thus, in this example, the unbalanced cell 410b and the filler cell 716 span two rows (i.e., the rows 514 and 516).

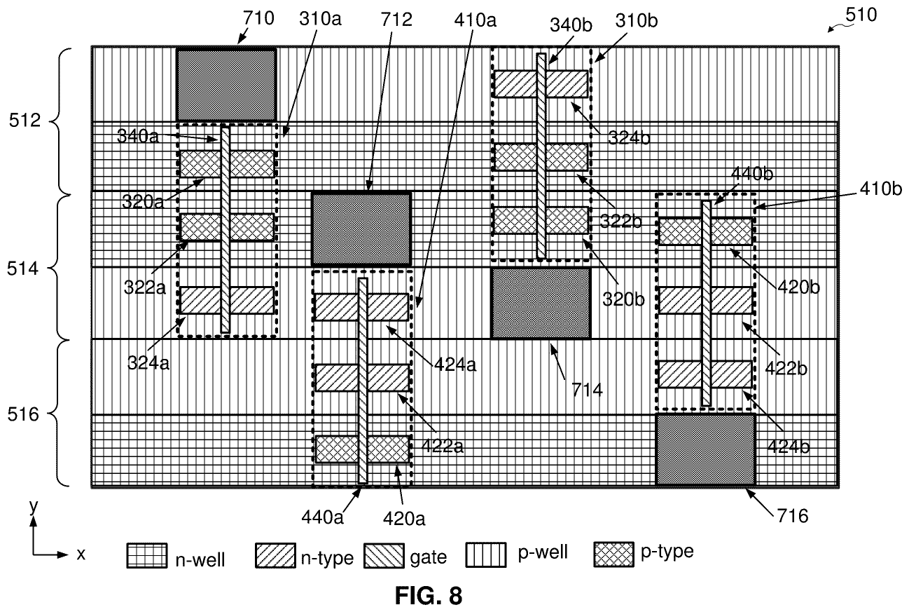

FIG. 8 shows the diffusion regions and the gates of the exemplary unbalanced cells 310a, 310b, 410a, and 410b.

For the cell 310a, the first p-type diffusion region 320a extends over the n-well in the row 512, the second p-type diffusion region 322a extends over the n-well in the row 514, and the n-type diffusion region 324a extends over the p-well in the row 514. The gate 340a extends across the row 514 in the y direction and extends partially into the row 512 in the y direction.

For the cell 310b, the first p-type diffusion region 320b extends over the n-well in the row 514, the second p-type diffusion region 322b extends over the n-well in the row 512, and the n-type diffusion region 324b extends over the p-well in the row 512. The gate 340b extends across the row 512 in the y direction and extends partially into the row 514 in the y direction.

For the cell 410a, the p-type diffusion region 420a extends over the n-well in the row 516, the first n-type diffusion region 422a extends over the p-well in the row 516, and the second n-type diffusion region 424a extends over the p-well in the row 514. The gate 440a extends across the row 516 in the y direction and extends partially into the row 514 in the y direction.

For the cell 410b, the p-type diffusion region 420b extends over the n-well in the row 514, the first n-type diffusion region 422b extends over the p-well in the row 514, and the second n-type diffusion region 424b extends over the p-well in the row 516. The gate 440b extends across the row 514 in the y direction and extends partially into the row 516 in the y direction.

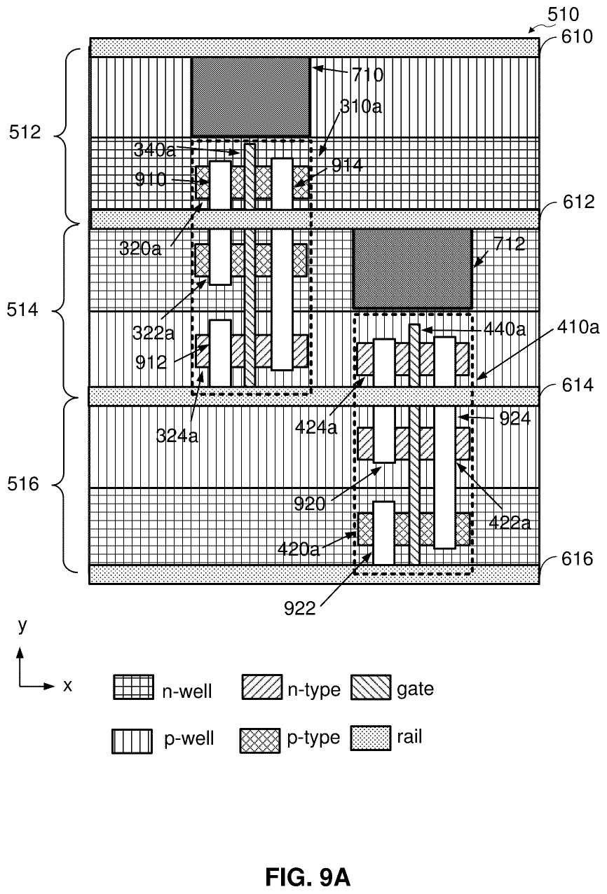

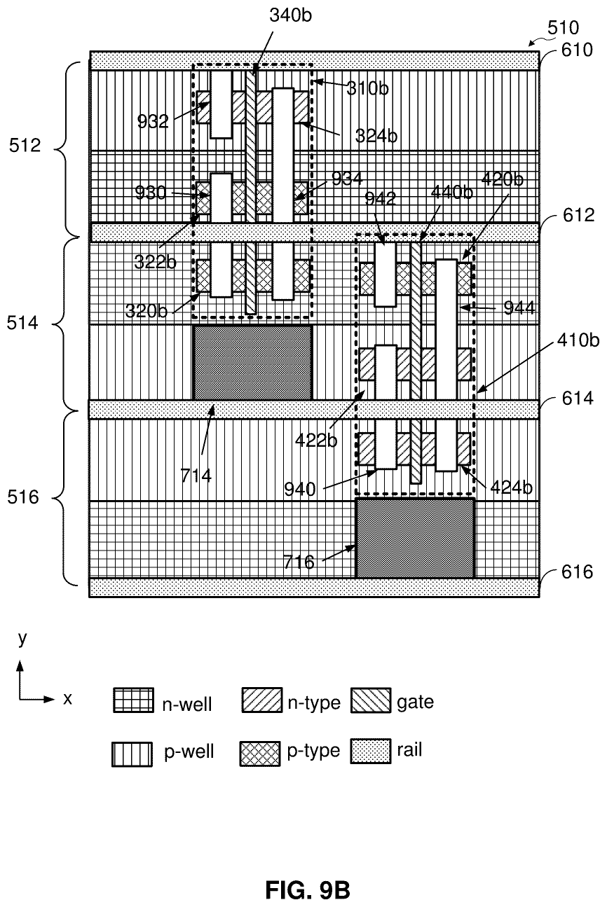

In certain aspects, the unbalanced cells 310a, 310b, 410a, and 410b may be used to provide drivers in one or more critical timing paths. In this regard, FIG. 9A shows an example in which the unbalanced cells 310a and 410a are used to implement drivers, and FIG. 9B shows an example in which the unbalanced cells 310b and 410b are used to implement drivers according to certain aspects. It is to be appreciated that the cells 310a, 310b, 410a, and 410b are not limited to the exemplary drivers shown in FIGS. 9A and 9B and that the cells 310a, 310b, 410a, and 410b may be used to implement other types of drivers or circuits.

In the example shown in FIG. 9A, the cell 310a includes a first contact 910 disposed on the p-type diffusion regions 320a and 322a, and a second contact 912 disposed on the n-type diffusion region 324a. The cell 310a also includes a third contact 914 disposed on the p-type diffusion regions 320a and 322a and the n-type diffusion region 324a on the opposite side of the gate 340a as the contacts 910 and 912 (i.e., the gate 340a is between the first contact 910 and the third contact 914 and between the second contact 912 and the third contact 914). Each of the contacts 910, 912, and 914 may be formed from contact layer MD in FIG. 1A. In this example, the gate 340a extends under the rail 612 to cross the boundary between the rows 512 and 514. The rail 612 extends over a portion of the cell 310a between the first p-type diffusion region 320a and the second p-type diffusion region 322a, as shown in FIG. 9A.

In this example, the first contact 910 is coupled to the rail 612 (e.g., VDD rail) by a via (e.g., VD via in FIG. 1A), and the second contact 912 is coupled to the rail 614 (e.g., VSS rail) by a via (e.g., VD via in FIG. 1A). The gate 340a may be coupled to input signal routing (not shown) for the driver in metal layer M0 by a via (e.g., VG via in FIG. 1A), and the third contact 914 may be coupled to output signal routing (not shown) for the driver in metal layer M0 by a via (e.g., VD via in FIG. 1A). In this example, the driver is inverting. However, it is to be appreciated that the present disclosure is not limited to this example.

In the example shown in FIG. 9A, the cell 410a includes a first contact 920 disposed on the n-type diffusion regions 422a and 424a, and a second contact 922 disposed on the p-type diffusion region 420a. The cell 410a also includes a third contact 924 disposed on the n-type diffusion regions 422a and 424a and the p-type diffusion region 420a on the opposite side of the gate 440a as the contacts 920 and 922 (i.e., the gate 440a is between the first contact 920 and the third contact 924 and between the second contact 922 and the third contact 924). Each of the contacts 920, 922, and 924 may be formed from contact layer MD in FIG. 1A. In this example, the gate 440a extends under the rail 614 to cross the boundary between the rows 514 and 516. The rail 614 extends over a portion of the cell 410a between the first n-type diffusion region 422a and the second n-type diffusion region 424a, as shown in FIG. 9A.

In this example, the first contact 920 is coupled to the rail 614 (e.g., VSS rail) by a via (e.g., VD via in FIG. 1A), and the second contact 922 is coupled to the rail 616 (e.g., VDD rail) by a via (e.g., VD via in FIG. 1A). The gate 440a may be coupled to input signal routing (not shown) for the driver in metal layer M0 by a via (e.g., VG via in FIG. 1A), and the third contact 924 may be coupled to output signal routing (not shown) for the driver in metal layer M0 by a via (e.g., VD via in FIG. 1A). In this example, the driver is inverting. However, it is to be appreciated that the present disclosure is not limited to this example.

In the example shown in FIG. 9B, the cell 310b includes a first contact 930 disposed on the p-type diffusion regions 320b and 322b, and a second contact 932 disposed on the n-type diffusion region 324b. The cell 310b also includes a third contact 934 disposed on the p-type diffusion regions 320b and 322b and the n-type diffusion region 324b on the opposite side of the gate 340b as the contacts 930 and 932 (i.e., the gate 340b is between the first contact 930 and the third contact 934 and between the second contact 932 and the third contact 934). Each of the contacts 930, 932, and 934 may be formed from contact layer MD in FIG. 1A. In this example, the gate 340b extends under the rail 612 to cross the boundary between the rows 512 and 514. The rail 612 extends over a portion of the cell 310b between the first p-type diffusion region 320b and the second p-type diffusion region 322b, as shown in FIG. 9B.

In this example, the first contact 930 is coupled to the rail 612 (e.g., VDD rail) by a via (e.g., VD via in FIG. 1A), and the second contact 932 is coupled to the rail 610 (e.g., VSS rail) by a via (e.g., VD via in FIG. 1A). The gate 340b may be coupled to input signal routing (not shown) for the driver in metal layer M0 by a via (e.g., VG via in FIG. 1A), and the third contact 934 may be coupled to output signal routing (not shown) for the driver in metal layer M0 by a via (e.g., VD via in FIG. 1A). In this example, the driver is inverting. However, it is to be appreciated that the present disclosure is not limited to this example.

In the example shown in FIG. 9B, the cell 410b includes a first contact 940 disposed on the n-type diffusion regions 422b and 424b, and a second contact 942 disposed on the p-type diffusion region 420b. The cell 410b also includes a third contact 944 disposed on the n-type diffusion regions 422b and 424b and the p-type diffusion region 420b on the opposite side of the gate 440b as the contacts 940 and 942 (i.e., the gate 440b is between the first contact 940 and the third contact 944 and between the second contact 942 and the third contact 944). Each of the contacts 940, 942, and 944 may be formed from contact layer MD in FIG. 1A. In this example, the gate 440b extends under the rail 614 to cross the boundary between the rows 514 and 516. The rail 614 extends over a portion of the cell 410b between the first n-type diffusion region 422b and the second n-type diffusion region 424b, as shown in FIG. 9B.

In this example, the first contact 940 is coupled to the rail 614 (e.g., VSS rail) by a via (e.g., VD via in FIG. 1A), and the second contact 942 is coupled to the rail 612 (e.g., VDD rail) by a via (e.g., VD via in FIG. 1A). The gate 440b may be coupled to input signal routing (not shown) for the driver in metal layer M0 by a via (e.g., VG via in FIG. 1A), and the third contact 944 may be coupled to output signal routing (not shown) for the driver in metal layer M0 by a via (e.g., VD via in FIG. 1A). In this example, the driver is inverting. However, it is to be appreciated that the present disclosure is not limited to this example.

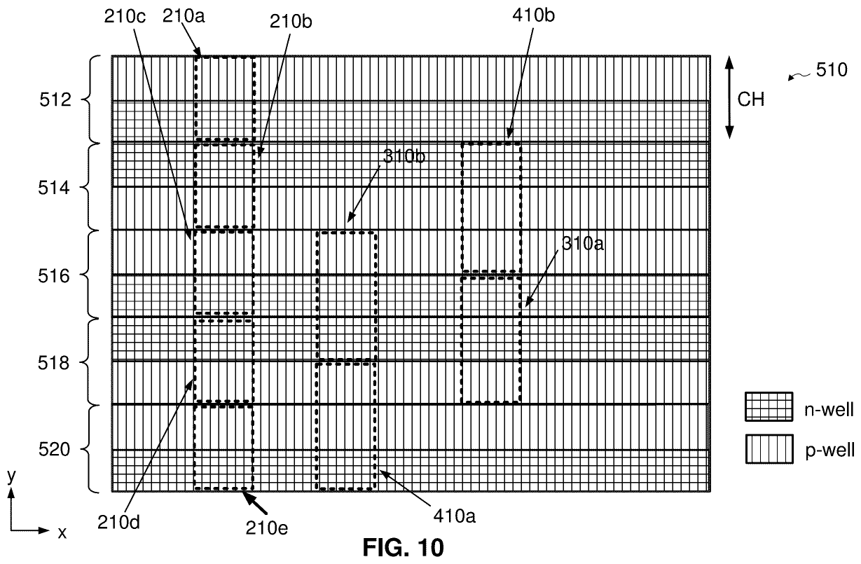

FIG. 10 shows an example in which the unbalanced cells 310b and 410a are placed adjacent to one another across three rows 516, 518, and 520 without a filler cell. In this example, the n-wells in rows 516 and 518 are used for the wide n-well 330 (shown in FIG. 3C) of the unbalanced cell 310b and the p-wells in rows 518 and 520 are used for the wide p-well 432 (shown in FIG. 4C) of the unbalanced cell 410a.

In this example, the cell 310b extends across the row 516 and partially across the row 518 in the y direction, and the cell 410a extends across the row 520 and partially across the row 518 in the y direction. The cell 310b abuts the cell 410a in the row 518 where the row 518 is between the rows 516 and 520 in the y direction. As used herein, a first cell abuts a second cell when there is no intervening cell disposed between the first cell and the second cell.

FIG. 10 also shows an example in which the unbalanced cells 410b and 310a are placed adjacent to one another across three rows 514, 516, and 518 without a filler cell. In this example, the n-wells in rows 516 and 518 are used for the wide n-well 330 (shown in FIG. 3A) of the unbalanced cell 310a and the p-wells in rows 514 and 516 are used for the wide p-well 432 (shown in FIG. 4A) of the unbalanced cell 410b.

In this example, the cell 310a extends across the row 518 and partially across the row 516 in the y direction, and the cell 410b extends across the row 514 and partially across the row 516 in the y direction. The cell 310a abuts the cell 410b in the row 516 where the row 516 is between the rows 514 and 518 in the y direction.

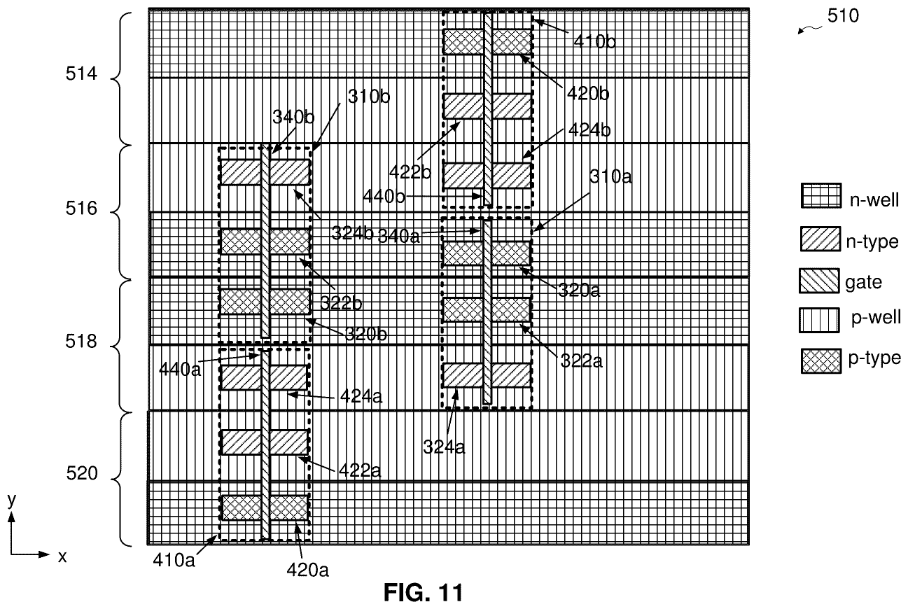

FIG. 11 shows the diffusion regions and the gates of the exemplary unbalanced cells 310a, 310b, 410a, and 410b for the exemplary layout shown in FIG. 10.

For the cell 310a, the first p-type diffusion region 320a extends over the n-well in the row 516, the second p-type diffusion region 322a extends over the n-well in the row 518, and the n-type diffusion region 324a extends over the p-well in the row 518. The gate 340a extends across the row 518 in the y direction and extends partially into the row 516 in the y direction.

For the cell 310b, the first p-type diffusion region 320b extends over the n-well in the row 518, the second p-type diffusion region 322b extends over the n-well in the row 516, and the n-type diffusion region 324b extends over the p-well in the row 516. The gate 340b extends across the row 516 in the y direction and extends partially into the row 518 in the y direction.

For the cell 410a, the p-type diffusion region 420a extends over the n-well in the row 520, the first n-type diffusion region 422a extends over the p-well in the row 520, and the second n-type diffusion region 424a extends over the p-well in the row 518. The gate 440a extends across the row 520 in the y direction and extends partially into the row 518 in the y direction.

For the cell 410b, the p-type diffusion region 420b extends over the n-well in the row 514, the first n-type diffusion region 422b extends over the p-well in the row 514, and the second n-type diffusion region 424b extends over the p-well in the row 516. The gate 440b extends across the row 514 in the y direction and extends partially into the row 516 in the y direction.

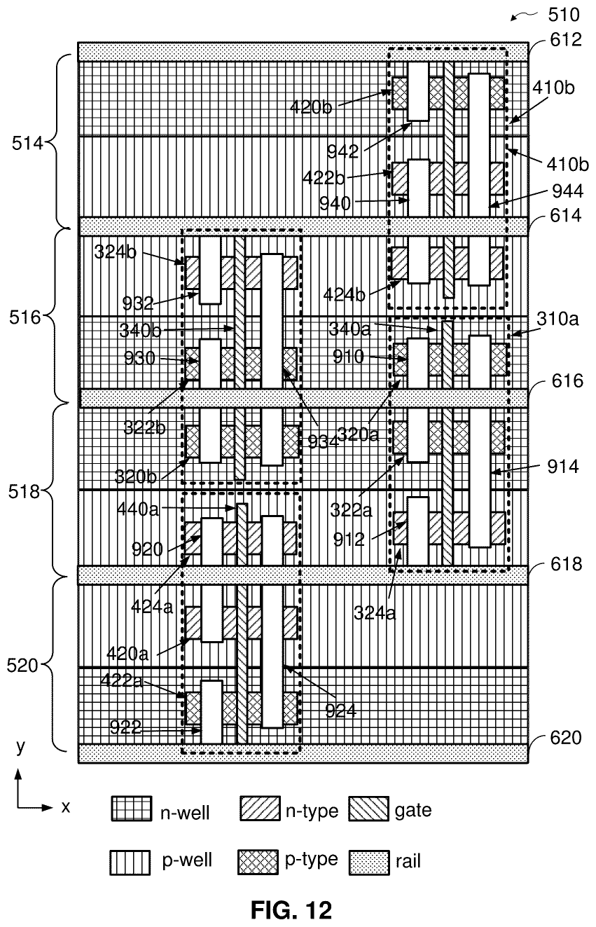

FIG. 12 shows an example in which the unbalanced cells 310a, 310b, 410a, and 410b are used to implement the exemplary drivers discussed above with reference to FIGS. 9A and 9B. In the example shown in FIG. 12, the first contact 910 of the cell 310a is coupled to the rail 616 (e.g., VDD rail) and the second contact 912 of the cell 310a is coupled to the rail 618 (e.g., VSS rail). The first contact 930 of the cell 310b is coupled to the rail 616 (e.g., VDD rail) and the second contact 932 of the cell 310b is coupled to the rail 614 (e.g., VSS rail). The first contact 920 of the cell 410a is coupled to the rail 618 (e.g., VSS rail) and the second contact 922 of the cell 410a is coupled to the rail 620 (e.g., VDD rail). The first contact 940 of the cell 410b is coupled to the rail 614 (e.g., VSS rail) and the second contact of the cell 410b is coupled to the rail 612 (e.g., VDD rail).

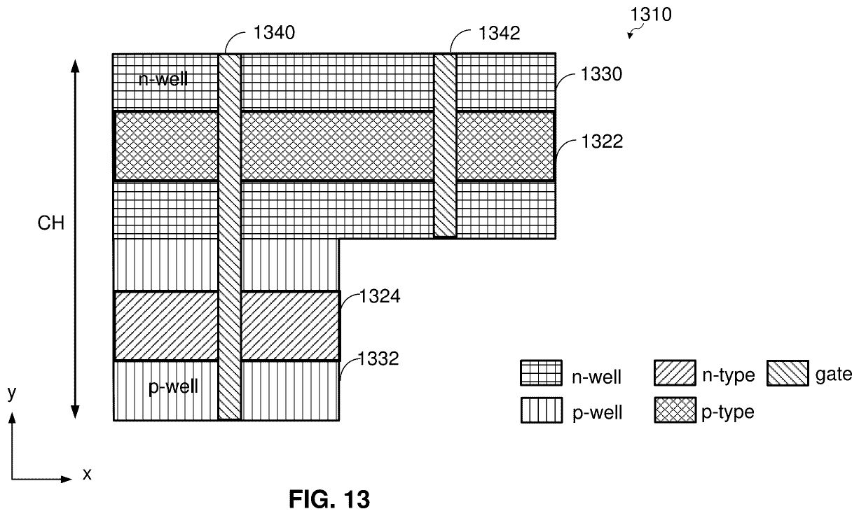

FIG. 13 shows another example of an unbalanced cell 1310 according to certain aspects. The unbalanced cell 1310 includes a p-type diffusion region 1322 extending over an n-well 1330 and an n-type diffusion region 1324 extending over a p-well 1332. The unbalanced cell 1310 also includes a first gate 1340 and a second gate 1342. The gates may also be referred to as fingers. The first gate 1340 extends over the p-type diffusion region 1322 and the n-type diffusion region 1324 in the y direction. The second gate 1342 extends over the p-type diffusion region 1322 in the y direction and is spaced apart from the first gate 1340 in the x direction. In this example, the p-type diffusion region 1322 extends over a longer length in the x direction than the n-type diffusion region 1324.

The p-type diffusion region 1322 and the first and second gates 1340 and 1342 form a PFET, and the n-type diffusion region 1324 and the first gate 1340 form an NFET. In this example, the PFET has two gates (i.e., first and second gates 1340 and 1342) while the NFET has one gate (i.e., first gate 1340). Thus, the PFET has an additional gate compared with the NFET. The additional gate and the longer length of the p-type diffusion region 1322 increases the strength of the PFET to provide a larger skew between the PFET strength and the NFET strength. An even larger skew may be achieved by making the p-type diffusion region 1322 wider than the n-type diffusion region 1324 in the y direction.

In this example, the cell 1310 has a height of 1 CH and can, therefore, be placed in a single row. It is to be appreciated that the orientation of the cell 1310 may be flipped in the x direction, the y direction, or both the x direction and the y direction relative to the exemplary orientation shown in FIG. 13.

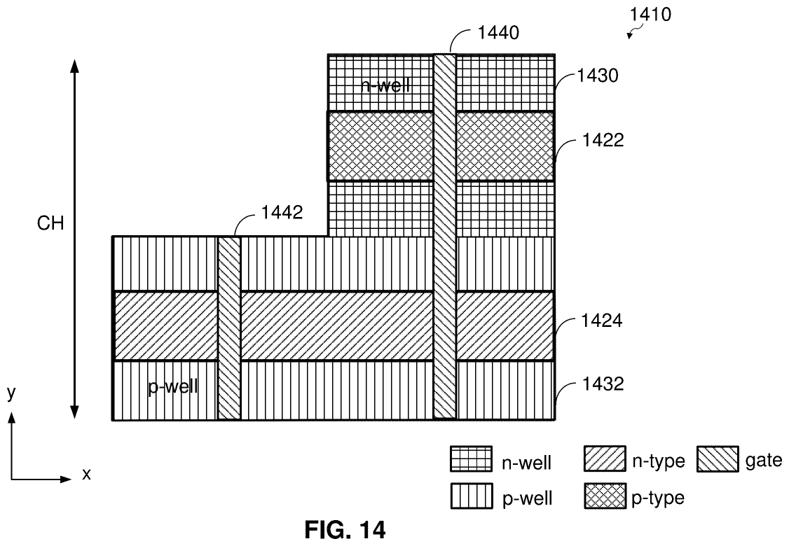

FIG. 14 shows another example of an unbalanced cell 1410 according to certain aspects. The unbalanced cell 1410 includes a p-type diffusion region 1422 extending over an n-well 1430 and an n-type diffusion region 1424 extending over a p-well 1432. The unbalanced cell 1410 also includes a first gate 1440 and a second gate 1442. The gates may also be referred to as fingers. The first gate 1440 extends over the p-type diffusion region 1422 and the n-type diffusion region 1424 in the y direction. The second gate 1442 extends over the n-type diffusion region 1424 in the y direction and is spaced apart from the first gate 1440 in the x direction. In this example, the n-type diffusion region 1424 extends over a longer length in the x direction than the p-type diffusion region 1422.

The n-type diffusion region 1424 and the first and second gates 1440 and 1442 form an NFET, and the p-type diffusion region 1422 and the first gate 1440 form a PFET. In this example, the NFET has two gates (i.e., first and second gates 1440 and 1442) while the PFET has one gate (i.e., first gate 1440). Thus, the NFET has an additional gate compared with the PFET. The additional gate and longer length of the n-type diffusion region 1424 increases the strength of the NFET to provide a larger skew between the NFET strength and the PFET strength. An even larger skew may be achieved by making the n-type diffusion region 1424 wider than the p-type diffusion region 1422 in the y direction.

In this example, the cell 1410 has a height of 1 CH and can, therefore, be placed in a single row. It is to be appreciated that the orientation of the cell 1410 may be flipped in the x direction, the y direction, or both the x direction and the y direction relative to the exemplary orientation shown in FIG. 14.

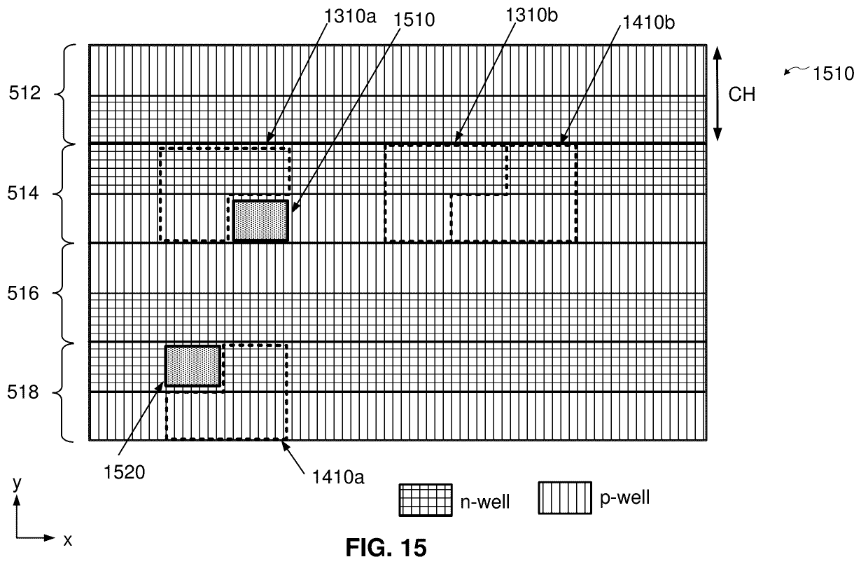

FIG. 15 shows an exemplary layout of various cells that may be placed in the rows 512, 514, 516, and 518. The boundary of each of the cells is delineated by a dotted line in FIG. 15. For each of illustration, the diffusion regions and the gate(s) of each cell is not shown in FIG. 15.

FIG. 15 shows an example of cells 1310a, 1310b, 1410a, and 1410b where each of the cells 1310a and 1310b is a separated instance of the cell 1310 and each of the cells 1410a and 1410b is a separated instance of the cell 1410. In the example in FIG. 15, the cell 1310a is placed in the row 514 with a first filler cell 1510 having a height of 0.5 CH, and the cell 1410a is placed in the row 518 with a second filler cell 1520 having a height of 0.5 CH.

FIG. 15 also shows an example in which the cell 1310b abuts the cell 1410b in the row 514 without a filler cell. A filler is not needed because the elongated portion of the cell 1410b fills the empty space of the cell 1310b, and the elongated portion of the cell 1310b fills the empty space of the cell 1410b, as shown in FIG. 15.

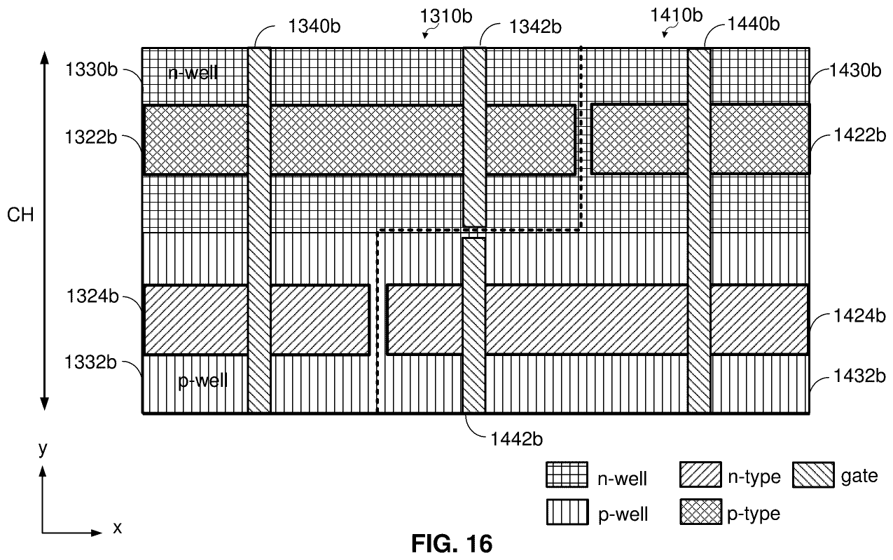

FIG. 16 shows a closeup view of the cells 1310b and 1410b. In this example, the second gate 1342b of the cell 1310b is aligned with the second gate 1442b of the cell 1410b in the x direction. Also, the p-type diffusion region 1322b of the cell 1310b is aligned with the p-type diffusion region 1422b of the cell 1410b in the y direction. The p-type diffusion regions 1322b and 1422b may be isolated by a diffusion cut. The n-type diffusion region 1324b of the cell 1310b is aligned with the n-type diffusion region 1424b of the cell 1410b in the y direction. The n-type diffusion regions 1324b and 1424b may be isolated by a diffusion cut. The n-well of the row 514 provides the n-well 1330b of the cell 1310b and the n-well 1430b of the cell 1410b, and the p-well of the row 514 provides the p-well 1332b of the cell 1310b and the p-well 1432b of the cell 1410b.

In certain aspects, the exemplary implementations shown in FIGS. 3A and 13 may be combined to provide a cell including a PFET with two p-type diffusion regions and two gates (i.e., two fingers) for a 4× increase in PFET strength. Similarly, the implementations in FIGS. 4A and 14 may be combined to provide a cell including an NFET with two n-type diffusion regions and two gates (i.e., two fingers) for a 4× increase in NFET strength.

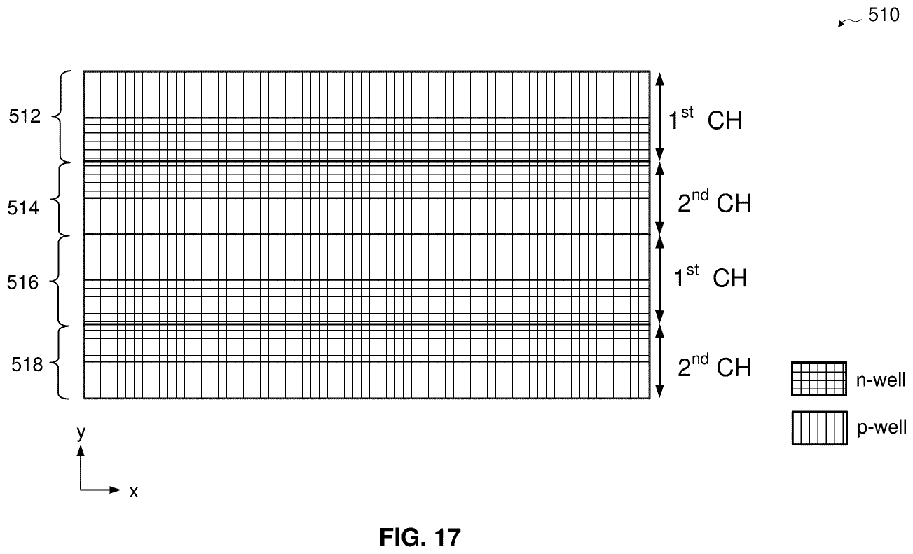

In the example in FIG. 5, the rows 512, 514, 516, 518, and 520 have a uniform height of 1 CH. However, it is to be appreciated that the rows 512, 514, 516, 518, and 520 are not limited to a uniform height. For example, FIG. 17 shows an exemplary row layout in which the rows 512, 514, 516, and 518 alternate between a first cell height (labeled “1^{st} CH”) and a second cell height (labeled “2^{nd} CH”) where the first cell height is greater than the second cell height. For example, the second cell height may be 0.75 of the first cell height, but is not limited to this example. In the example shown in FIG. 17, each of the rows 512 and 516 has the first cell height and each of the rows 514 and 518 has the second cell height.

In one example, the rows 512 and 516 with the first cell height may be used for higher-performance cells while the rows 514 and 518 with the second cell height may be used for lower-performance cells. In this example, each of the higher-performance cells may have a height equal to the first cell height and each of the lower-performance cells may have a height equal to the second cell height (which is shorter than the first cell height). For example, the higher-performance cells may be used in a critical path of a digital circuit while the lower-performance cells may be used in portions of the digital circuit that do not require the higher performance to meet a timing specification for the digital circuit. In this example, the shorter height of the lower-performance cells helps improve cell density (i.e., increase the number of cells in a given area).

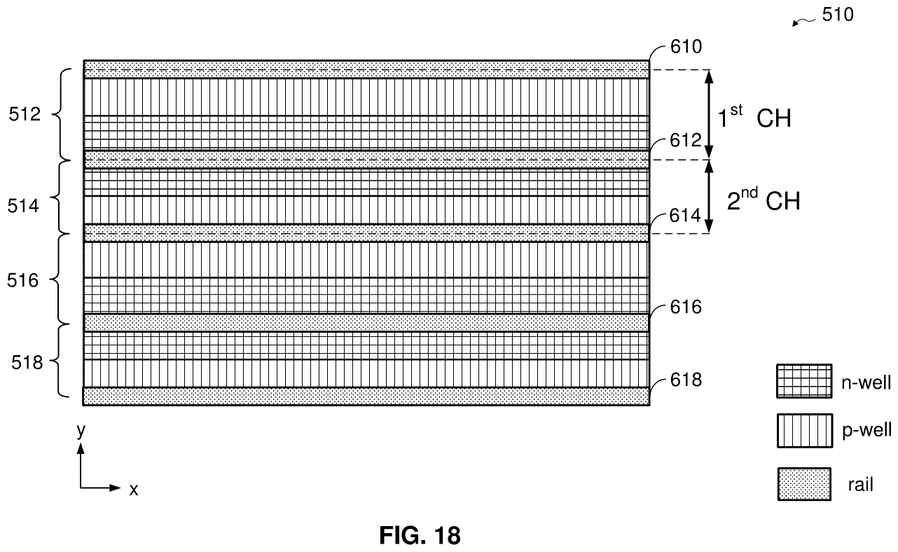

FIG. 18 shows an example of the rails 610, 612, 614, 616, and 618 placed over the boundaries of adjacent rows according to certain aspects. In this example, the rails 610 and 612 are spaced apart by the first cell height, the rails 612 and 614 are spaced apart by the second cell height, the rails 614 and 616 are spaced apart by the first cell height, and the rails 616 and 618 are spaced apart by the second cell height.

The exemplary cells 310a, 310b, 410a, and 410b may be placed in the exemplary row layout shown in FIGS. 17 and 18. For example, each of the cells 310a, 310b, 410a, and 410b may be placed in one of the rows and partially in an adjacent row. In this example, each of the cells 310a, 310b, 410a, and 410b may have a height approximately equal to 1.5 times the first cell height and greater than 1.5 times the second cell height since the second cell height is shorter than the first cell height. However, it is to be appreciated that the present disclosure is not limited to this example. In general, the height of each of the cells 310a, 310b, 410a, and 410b is greater than the height of a row (e.g., the first cell height or the second cell height) and hence greater than the height between adjacent rails (e.g., between rails 612 and 614).

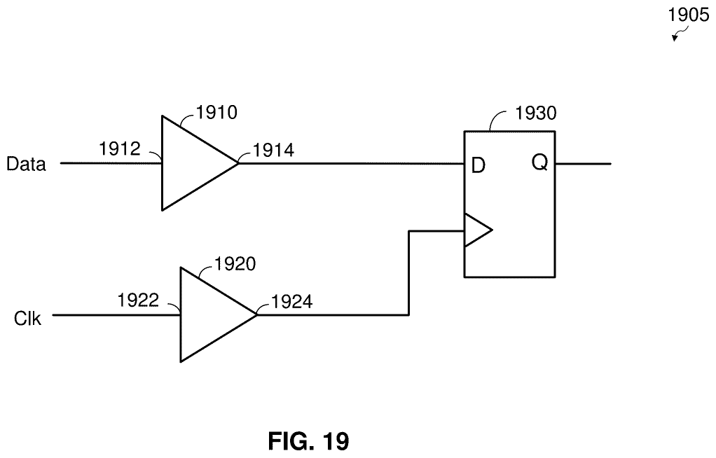

FIG. 19 shows an example of a digital block 1905 in which aspects of the present disclosure may be used. In this example, the digital block 1905 includes a first driver 1910, a second driver 1920, and a flip-flop 1930. The first driver 1910 is in a data path of the flip-flop 1930 and the second driver 1920 is in the clock path of the flip-flop 1930.

In this example, the first driver 1910 has an input 1912 and an output 1914 coupled to a data input (labeled “D”) of the flip-flop 1930. The first driver 1910 is configured to receive a data signal at the input 1912 and drive the data input of the flip-flop 1930 with the data signal. The first driver 1910 may be implemented with any one of the exemplary unbalanced cells discussed above (e.g., to provide a desired rise time or fall time for the data signal to meet a timing requirement of the flip-flop 1930). For example, when the first driver 1910 is implemented with any one of the cells 310a, 310b, 410a, and 410b shown in FIGS. 9A and 9B, the input 1912 of the first driver 1910 may be coupled to the gate of the cell (e.g., respective one of the gates 340a, 340b, 440a, and 440b) and the output 1914 of the first driver 1910 may be coupled to the third contact of the cell (e.g., respective one of the third contacts, 914, 924, 934, and 944). However, it is to be appreciated that the present disclosure is not limited to this example.

In this example, the second driver 1920 has an input 1922 and an output 1924 coupled to a clock input of the flip-flop 1930. The second driver 1920 is configured to receive a clock signal at the input 1922 and drive the clock input of the flip-flop 1930 with the clock signal. The second driver 1920 may be implemented with any one of the exemplary unbalanced cells discussed above. The clock signal may come from a clock generator (e.g., phase-locked loop (PLL)).

The flip-flop 1930 is configured to latch a logic value of the data signal at the data input (labeled “D”) of the flip-flop 1930 on an edge of the clock signal (e.g., rising edge or falling edge of the clock signal) and output the latched logic value at the output (labeled “Q”) of the flip-flop 1930. The output of the flip-flop 1930 may be coupled to combinational logic, sequential logic, or the like.

Implementation examples are described in the following numbered clauses:
1. A chip, comprising:
   a first rail extending in a first direction;
   a second rail extending in the first direction; and
   a first cell, the first cell comprising:
      a first p-type diffusion region extending in the first direction;
      a second p-type diffusion region extending in the first direction;
      a first n-type diffusion region extending in the first direction; and
      a first gate extending over the first p-type diffusion region, the second p-type diffusion region, and the first n-type diffusion region in a second direction perpendicular to the first direction.
2. The chip of clause 1, wherein the first rail and the second rail are spaced apart by a first height in the second direction, and the first cell has a second height in the second direction greater than the first height.
3. The chip of clause 2, wherein the second height is approximately equal to 1.5 times the first height.
4. The chip of clause 3, further comprising a filler cell abutting the first cell, wherein the filler cell has a third height in the second direction approximately equal to 0.5 times the first height.
5. The chip of any one of clauses 1 to 4, wherein the second rail extends over a portion of the first cell between the first p-type diffusion region and the second p-type diffusion region.
6. The chip of clause 5, further comprising:
   a first contact disposed on the first n-type diffusion region, wherein the first contact is coupled to the first rail; and
   a second contact disposed on the first p-type diffusion region and the second p-type diffusion region, wherein the second contact is coupled to the second rail.
7. The chip of clause 6, wherein the first rail comprises a ground rail and the second rail comprises a supply rail.
8. The chip of any one of clauses 1 to 7, further comprising:
   a second cell abutting the first cell, the second cell comprising:
      a second n-type diffusion region extending in the first direction;
      a third n-type diffusion region extending in the first direction;
      a third p-type diffusion region extending in the first direction; and
      a second gate extending over the second n-type diffusion region, the third n-type diffusion region, and the third p-type diffusion region in the second direction, wherein the second gate is aligned with the first gate in the first direction.
9. The chip of clause 8, wherein the first rail and the second rail are spaced apart by a first height in the second direction, the first cell has a second height in the second direction greater than the first height, and the second cell has a third height in the second direction greater than the first height.
10. The chip of clause 9, wherein the second height is approximately equal to 1.5 times the first height.
11. The chip of clause 10, wherein the third height is approximately equal to 1.5 times the first height.
12. The chip of any one of clauses 8 to 11, further comprising:
   a third rail extending in the first direction; and
   a fourth rail extending in the first direction.
13. The chip of clause 12, wherein:
   the second rail extends over a portion of the first cell between the first p-type diffusion region and the second p-type diffusion region; and
   the third rail extends over a portion of the second cell between the second n-type diffusion region and the third n-type diffusion region.
14. The chip of clause 13, wherein the second rail comprises a supply rail and the third rail comprises a ground rail.
15. The chip of clause 13 or 14, wherein the first rail extends over a side of the first cell and the fourth rail extends over a side of the second cell.
16. The chip of clause 15, wherein the first rail comprises a first ground rail, the second rail comprises a first supply rail, the third rail comprises a second ground rail, and the fourth rail comprises a second supply rail.
17. The chip of any one of clauses 13 to 16, further comprising:
   a first contact disposed on the first n-type diffusion region, wherein the first contact is coupled to the first rail;
   a second contact disposed on the first p-type diffusion region and the second p-type diffusion region, wherein the second contact is coupled to the second rail;
   a third contact disposed on the second n-type diffusion region and the third n-type diffusion region, wherein the third contact is coupled to the third rail; and
   a fourth contact disposed on the third p-type diffusion region, wherein the fourth contact is coupled to the fourth rail.
18. The chip of clause 17, wherein the first rail comprises a first ground rail, the second rail comprises a first supply rail, the third rail comprises a second ground rail, and the fourth rail comprises a second supply rail.
19. The chip of any one of clauses 1 to 18, wherein at least one of the first p-type diffusion region and the second p-type diffusion region has a wider width in the second direction than the first n-type diffusion region.
20. The chip of any one of clauses 1 to 18, wherein each of the first p-type diffusion region and the second p-type diffusion region has a wider width in the second direction than the first n-type diffusion region.
21. The chip of any one of clauses 1 to 20, further comprising a filler cell abutting the first cell.
22. A chip, comprising:
   a first rail extending in a first direction;
   a second rail extending in the first direction, wherein the first rail and the second rail are spaced apart by a first height in a second direction perpendicular to the first direction;
   a first cell, wherein the first cell has a second height in the second direction approximately equal to the first height, the first cell comprising:
      a first n-type diffusion region extending in the first direction;
      a first p-type diffusion region extending in the first direction, wherein the first p-type diffusion region has a longer length in the first direction than the first n-type diffusion region;
      a first gate extending over the first p-type diffusion region and the first n-type diffusion region in the second direction; and
      a second gate extending over the first p-type diffusion region in the second direction, wherein the second gate is spaced apart from the first gate in the first direction.
23. The chip of clause 22, wherein the first rail extends over a first side of the first cell and the second rail extends over a second side of the first cell.
24. The chip of clause 22 or 23, further comprising:
   a second cell abutting the first cell, wherein the second cell has a third height in the second direction approximately equal to the first height, the second cell comprising:
      a second p-type diffusion region extending in the first direction, wherein the second p-type diffusion region is aligned with the first p-type diffusion region in the second direction;
      a second n-type diffusion region extending in the first direction, wherein the second n-type diffusion region has a longer length in the first direction than the second p-type diffusion region, and the second n-type diffusion region is aligned with the first n-type diffusion region in the second direction;
      a third gate extending over the second p-type diffusion region and the second n-type diffusion region in the second direction; and
      a fourth gate extending over the second n-type diffusion region in the second direction, wherein the fourth gate is spaced apart from the third gate in the first direction.
25. The chip of clause 24, wherein the fourth gate is aligned with the second gate in the first direction.
26. The chip of clause 25, wherein the first rail extends over a first side of the first cell and a first side of the second cell and the second rail extends over a second side of the first cell and a second side of the second cell.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value. For example, a first height approximately equal to a second height is within 90 percent to 110 percent of the second height.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a first rail extending in a first direction;
a second rail extending in the first direction; and
a first cell, the first cell comprising:
a first p-type diffusion region extending in the first direction;
a second p-type diffusion region extending in the first direction;
a first n-type diffusion region extending in the first direction; and
a first gate extending over the first p-type diffusion region, the second p-type diffusion region, and the first n-type diffusion region in a second direction perpendicular to the first direction.

2. The chip of claim 1, wherein the first rail and the second rail are spaced apart by a first height in the second direction, and the first cell has a second height in the second direction greater than the first height.

3. The chip of claim 2, wherein the second height is approximately equal to 1.5 times the first height.

4. The chip of claim 3, further comprising a filler cell abutting the first cell, wherein the filler cell has a third height in the second direction approximately equal to 0.5 times the first height.

5. The chip of claim 1, wherein the second rail extends over a portion of the first cell between the first p-type diffusion region and the second p-type diffusion region.

6. The chip of claim 5, further comprising:
a first contact disposed on the first n-type diffusion region, wherein the first contact is coupled to the first rail; and
a second contact disposed on the first p-type diffusion region and the second p-type diffusion region, wherein the second contact is coupled to the second rail.

7. The chip of claim 1, further comprising:
a second cell abutting the first cell, the second cell comprising:
a second n-type diffusion region extending in the first direction;
a third n-type diffusion region extending in the first direction;
a third p-type diffusion region extending in the first direction; and
a second gate extending over the second n-type diffusion region, the third n-type diffusion region, and the third p-type diffusion region in the second direction, wherein the second gate is aligned with the first gate in the first direction.

8. The chip of claim 7, wherein the first rail and the second rail are spaced apart by a first height in the second direction, the first cell has a second height in the second direction greater than the first height, and the second cell has a third height in the second direction greater than the first height.

9. The chip of claim 8, wherein the second height is approximately equal to 1.5 times the first height.

10. The chip of claim 9, wherein the third height is approximately equal to 1.5 times the first height.

11. The chip of claim 7, further comprising:
a third rail extending in the first direction; and
a fourth rail extending in the first direction.

12. The chip of claim 11, wherein:
the second rail extends over a portion of the first cell between the first p-type diffusion region and the second p-type diffusion region; and
the third rail extends over a portion of the second cell between the second n-type diffusion region and the third n-type diffusion region.

13. The chip of claim 12, wherein the first rail extends over a side of the first cell and the fourth rail extends over a side of the second cell.

14. The chip of claim 12, further comprising:
a first contact disposed on the first n-type diffusion region, wherein the first contact is coupled to the first rail;
a second contact disposed on the first p-type diffusion region and the second p-type diffusion region, wherein the second contact is coupled to the second rail;
a third contact disposed on the second n-type diffusion region and the third n-type diffusion region, wherein the third contact is coupled to the third rail; and
a fourth contact disposed on the third p-type diffusion region, wherein the fourth contact is coupled to the fourth rail.

15. The chip of claim 14, wherein the first rail comprises a first ground rail, the second rail comprises a first supply rail, the third rail comprises a second ground rail, and the fourth rail comprises a second supply rail.

16. The chip of claim 1, wherein at least one of the first p-type diffusion region and the second p-type diffusion region has a wider width in the second direction than the first n-type diffusion region.

17. A chip, comprising:
a first rail extending in a first direction;
a second rail extending in the first direction, wherein the first rail and the second rail are spaced apart by a first height in a second direction perpendicular to the first direction;
a first cell, wherein the first cell has a second height in the second direction approximately equal to the first height, the first cell comprising:
a first n-type diffusion region extending in the first direction;
a first p-type diffusion region extending in the first direction, wherein the first p-type diffusion region has a longer length in the first direction than the first n-type diffusion region;
a first gate extending over the first p-type diffusion region and the first n-type diffusion region in the second direction; and
a second gate extending over the first p-type diffusion region in the second direction, wherein the second gate is spaced apart from the first gate in the first direction.

18. The chip of claim 17, further comprising:
a second cell abutting the first cell, wherein the second cell has a third height in the second direction approximately equal to the first height, the second cell comprising:
a second p-type diffusion region extending in the first direction, wherein the second p-type diffusion region is aligned with the first p-type diffusion region in the second direction;
a second n-type diffusion region extending in the first direction, wherein the second n-type diffusion region has a longer length in the first direction than the second p-type diffusion region, and the second n-type diffusion region is aligned with the first n-type diffusion region in the second direction;
a third gate extending over the second p-type diffusion region and the second n-type diffusion region in the second direction; and
a fourth gate extending over the second n-type diffusion region in the second direction, wherein the fourth gate is spaced apart from the third gate in the first direction.

19. The chip of claim 18, wherein the fourth gate is aligned with the second gate in the first direction.

20. The chip of claim 19, wherein the first rail extends over a first side of the first cell and a first side of the second cell and the second rail extends over a second side of the first cell and a second side of the second cell.
